(19) United States
(12) Patent Application Publication
(10) Pub. No.: US 2025/0189570 A1
(43) Pub. Date: Jun. 12, 2025

(54) SYSTEM AND METHOD FOR VOLUMETRIC SCANNING OF RADIO FREQUENCY SIGNALS

(71) Applicant: KEYSIGHT TECHNOLOGIES, INC., SANTA ROSA, CA (US)

(72) Inventors: Prasadh Ramachandran, Oulu (FI); Gregory Douglas Vanwiggeren, San Jose, CA (US); Gregory Eng, Santa Clara, CA (US); Matthew Condie, Santa Rosa, CA (US); Michael Foegelle, Austin, TX (US)

(21) Appl. No.: 18/977,837

(22) Filed: Dec. 11, 2024

Related U.S. Application Data
(60) Provisional application No. 63/627,408, filed on Jan. 31, 2024.
(60) Provisional application No. 63/609,033, filed on Dec. 12, 2023.

(51) Int. Cl. G01R 29/08; G01R 29/10

(52) U.S. Cl. CPC G01R 29/0878; G01R 29/10

(57) ABSTRACT

A system for scanning radio frequency signals to and/or from a fixed device under test (DUT) within a volume of space around the DUT is disclosed. The system includes a gantry with a carrier robotically movable along a beam in a first direction, and a robotic arm mounted to the carrier and extending from the beam. The gantry moves the robotic arm along the beam in a second direction orthogonal to the first direction. An RF probe is mounted to a free end of the robotic arm and is configured to communicate with the antenna under test (AUT) of the DUT. A control system coordinates movements of the gantry and robotic arm to move the RF probe in a scanning pattern about the DUT.

### CROSS-REFERENCE TO RELATED APPLICATION(S)

A claim of priority is made to U.S. provisional application No. 63/609,033, filed Dec. 12, 2023, and to U.S. provisional application No. 63/627,408, filed Jan. 31, 2024, the disclosures of which are incorporated herein by reference in their entireties.

### FIELD

The present disclosure generally relates to systems and methods for scanning radio frequency signals to and/or from a fixed device under test within a volume of space around the device, particularly in the context of antenna testing.

### BACKGROUND

Wireless communication technology has seen rapid advancements in recent years. One such advancement is the use of phased arrays, which have transitioned from being primarily used in the aerospace and defense industry to being incorporated into commercial products. Phased arrays are now being used in 5G millimeter wave (mmWave) communications, enabling the creation of extremely narrow beams. These arrays typically use variable gain amplifiers and phase shifters to synthesize a plane wave in the desired direction from a common RF signal.

Another development in the wireless communication industry is the emergence of low earth orbit (LEO) satellite internet service. This technology has led to the replacement of traditional reflector-based residential satellite dishes with flat panel phased array antennas. These antennas are expected to play a pivotal role in the development of non-terrestrial networks for 6G applications, which aim to provide cell-phone coverage in remote areas. These networks are expected to employ satellites, balloons, and/or high-altitude gliders equipped with multiple phased-array antennas to facilitate communication between ground-stations, satellites, and mobile users.

However, testing these advanced antenna systems presents several challenges. Traditional antenna pattern measurement techniques, such as far-field ranges, compact ranges, or near-field scanners, are not suitable for testing these systems due to the tight integration of the antenna with the radio architecture. This integration makes it impractical to introduce an RF connector between the radio circuitry and the antenna, necessitating over-the-air (OTA) testing. Furthermore, the size of the phased arrays, particularly for large devices such as satellites or vehicles, necessitates the use of large compact antenna test ranges (CATR) with parabolic reflectors to generate a uniform plane wave that illuminates the antenna under test (AUT).

Industrial robots and collaborative robots (cobots) have been introduced into the industry to replace one or both axes of a two-axis scanner for near-field scanning of the AUT. However, these robotic systems have limitations, such as the inability to maintain a spherical surface as the AUT is scanned, and the difficulty of accurately positioning the robot due to the inherent sag and other related effects across each joint of the robot. Furthermore, the use of robotic arms for near-field scanning requires the use of expensive laser interferometer trackers to calibrate or record the real position at each step in the measurement process.

### SUMMARY

In general, in a first aspect, systems of the inventive concepts feature a gantry having a carrier robotically movable along a beam in a first direction. A robotic arm, having a fixed end mounted to the carrier and extending from the beam, is moved by the gantry along the beam in a second direction orthogonal to the first direction. An RF probe is mounted to a free end of the robotic arm and is configured to communicate with the antenna under test (AUT) of a fixed device under test (DUT) within a volume of space around the DUT. A control system is configured to coordinate movements of the gantry and robotic arm to move the RF probe in a scanning pattern about the DUT.

Embodiments of the system may include one or more of the following features. The first and second directions may extend horizontally in parallel with a support surface of a chamber containing the system, and the robotic arm may extend downwardly from the beam. Alternatively, the first direction may extend horizontally and the second direction may extend vertically, and the robotic arm may extend horizontally from the beam. The robotic arm may have at least four degrees of freedom or at least six degrees of freedom. The RF probe may be a compact antenna test range (CATR) assembly. The DUT may be a satellite, a terrestrial vehicle, an aircraft, a watercraft or an aerospace vehicle, and a volume of space traversed by the RF probe is at least as large as the volume of space around the DUT.

In another aspect, the method for scanning radio frequency (RF) signals to and/or from a fixed device under test (DUT) within a volume of space around the DUT is provided. The method includes providing a gantry having a carrier robotically movable along a beam in a first direction, providing a robotic arm having a fixed end mounted to the carrier and extending from the beam, the gantry configured to move the robotic arm along the beam in a second direction orthogonal to the first direction, providing an RF probe mounted to a free end of the robotic arm and configured to communicate with the AUT, and coordinating movements of the gantry and robotic arm to move the RF probe in a scanning pattern about the DUT.

### BRIEF DESCRIPTION OF DRAWINGS

The above and other aspects and features of the inventive concepts will become readily apparent from the detailed description that follows, with reference to the accompanying drawings, in which:

FIG. 1 is a photo image illustrating a large Compact Antenna Test Chamber for satellite testing of the prior art;

FIG. 2 is another photo image showing a Compact Antenna Test Range with a compound reflector for satellite testing of the prior art;

FIGS. 3A through 3D are conceptual drawings for reference in describing a “robot tool workspace” generated by an off-the-shelf robot simulation and programming tool for a robot mounted to the ceiling above a desired test volume;

FIG. 4 illustrates a system for scanning radio frequency (RF) signals to and/or from a fixed device under test (DUT) within a volume of space around the DUT according to an embodiment of the inventive concepts;

FIG. 5A shows the orientation of the coordinate system in a polar configuration so that theta=0 along the orthogonal boresight direction of the antenna under test (AUT);

FIG. 5B illustrates an alternate spherical scan algorithm, where equatorial or azimuth/elevation coordinates are used about the boresight direction;

FIG. 5C shows the range of the allowed angles for each cut varies around the hemisphere based on the total angle from the boresight axis;

FIG. 6A illustrates a 15-degree grid from the polar spherical configuration projected on a plane for theta angles up to 75 degrees;

FIG. 6B illustrates the 15-degree grid for the azimuth/elevation configuration projected on a plane for azimuth and elevation ranges up to +75 degrees in azimuth and elevation about the boresight;

FIG. 7 illustrates how the volumetric positioning system may be used to alter the center coordinates of test volume configurations in order to scan different antenna under tests or other items at different locations on the device under test;

FIGS. 8A and 8B illustrate the relationship between the angle from zenith for both a satellite and a ground station and the corresponding orbital angle and the range of azimuth angles over which communication is maintained projected on the surface of the Earth;

FIGS. 9A and 9B plot the range of zenith angles for a satellite passing directly overhead and the corresponding angular velocities seen by the ground station as the satellite passes;

FIG. 10 shows the collection of variables that are used to solve the simple zenith trajectory case;

FIG. 11 illustrates a system in which a second gantry beam and carrier with a second robot arm and CATR probe are used to generate a second plane-wave beam to the desired test volume in accordance with an embodiment of the inventive concepts;

FIG. 12 illustrates how the system of FIG. 11 could be used in other methodology to test other scenarios such as MIMO/massive MIMO, multiple simultaneous beams from the same AUT, or signal-to-interference (SIR) testing on a single AUT;

FIG. 13 illustrates how the base of the robot moves along the reverse of the path in the robot tool workspace in order to maintain the center of the test volume as the probe is moved through the desired range of angles;

FIG. 14 shows how the elbow can be locked with the arm nearly straight and the adjacent wrist joint of the robot can be kept in an almost right-angle orientation that gives the maximum angular extension of the reflector/probe when the arm is near vertical;

FIG. 15 illustrates how the phi-axis rotation is accomplished by moving the X-Y gantry in a circle at the current radius associated with the theta angle and rotating the top vertical shoulder joint of the robot in the opposite direction to compensate for the circular motion of the gantry carrier and robot base;

FIG. 16 illustrates an alternate scan algorithm where the gantry carrier and robot arm move along a circular arc as the reflector moves up and across the test volume;

FIG. 17 is a pulse diagram for reference in describing the use of multiple axes with varied rates of motion to produce a single motion of the probe tool about a virtual axis and triggering generated proportional to the resulting angular motion rate; and

FIG. 18 illustrates a generic control system that includes a computer system communicating with a gantry servo, a robot servo, RF probe control circuits and DUT control circuits.

### DETAILED DESCRIPTION

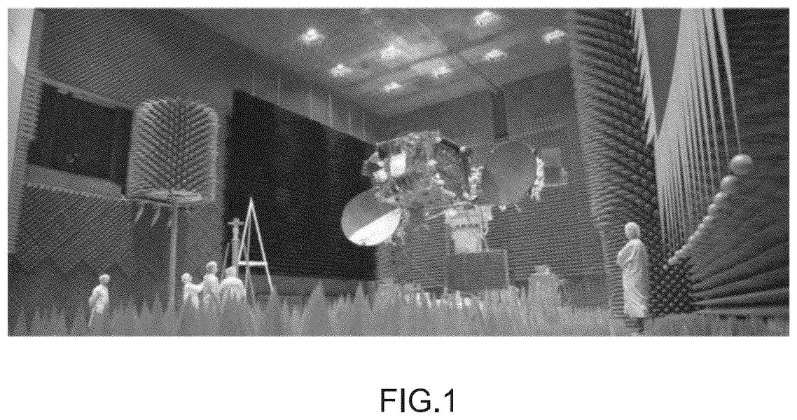

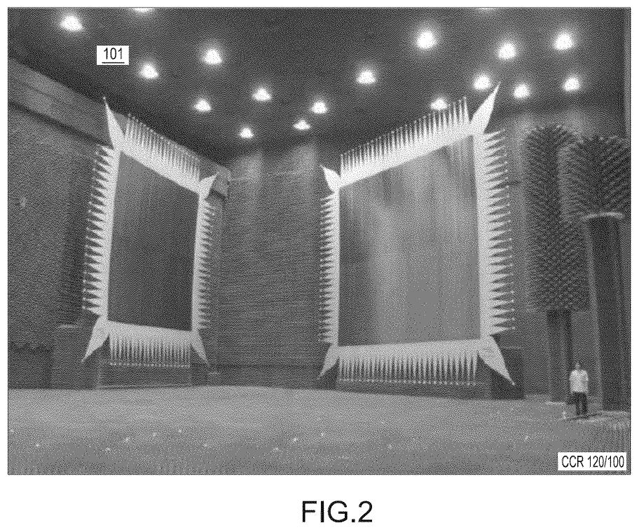

Referring to FIG. 1 and FIG. 2, Large Compact Antenna Test Chambers 100 and 101 for satellite testing are illustrated. These chambers are designed to maintain less than 30 μm RMS accuracy across the whole surface of both reflectors. In particular, FIG. 1 shows a prior art example of a Compact Antenna Test Range with a compound reflector for satellite testing at Airbus. The range feed can be seen on the left and the bottom of the sub-reflector on the right.

Moving on to FIG. 2, another example of a prior art Compact Antenna Test Range with a compound reflector for satellite testing at Airbus is shown. In this configuration, the main reflector is positioned on the right with the sub-reflector on the left. The feed is located between the two round columns on the right. These chambers are typically isolated from external radio interference, with inner walls studded with foam pyramids to minimize radio-frequency signal reflections, mimicking the void of space. The physical size and the requisite distance from the device to the reflectors and feed antennas mean that the primary practical way to evaluate the antenna performance from multiple directions is to manipulate the DUT in two dimensions. This can be a substantial challenge, especially for large vehicles, and can also imply slow acceleration and movement speeds due to the mass of the positioning systems.

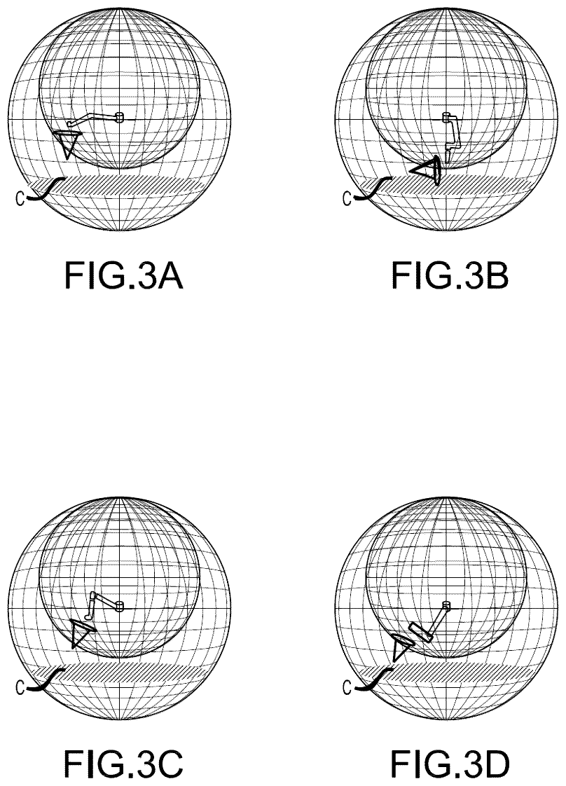

Turning to FIGS. 3A through 3D, a prior art “robot tool workspace” is illustrated. This workspace is generated by an off-the-shelf robot simulation and programming tool, such as RoboDK, for a robot mounted to the ceiling above a desired test volume. The figures illustrate all of the possible places that the chosen robot could place the specified tool tip point “C”. In this case, point “C” represents the desired center of the test volume relative to the reflector, and its placement is based entirely upon the range of motion of each axis of the robot.

FIGS. 3A and 3B illustrate two extremes of the reach of the robot arm in its own workspace, which is smaller than that of the robot plus tool. In these figures, the wrist of the robot has been oriented to position the tool tip at the same point. This would represent the maximum range of a single axis scan, i.e., theta, around the DUT. However, it is already apparent that this range is limited to something less than 90 degrees.

FIGS. 3C and 3D show two possible paths the robot could take to achieve this, both of which are valid in the given workspace, but neither of which are possible in practice. In the first case, as shown in FIG. 3C, the elbow of the robot would collide with the ceiling. In the second case, as shown in FIG. 3D, the elbow is constrained to point down, but then collides with the reflector. These limitations highlight the challenges of using a robotic arm for near-field scanning of the AUT.

These figures illustrate the inherent limitations of the prior art robotic tool workspace. The range of motion of the robot arm, the potential for collisions, and the physical location of the robot base relative to the AUT all contribute to the limitations of the workspace. These limitations can restrict the ability of the robot to accurately and efficiently scan the AUT, highlighting the challenges of using robotic systems for testing advanced antenna systems.

In their simplest form, the invention concepts consist of a multi-axis positioning system capable of manipulating an elongated object in up to six degrees of freedom (three rotational and three translational) throughout a large area, to which an RF measurement system is attached in order to perform radiated or over-the-air measurements of antennas, arrays, or other antenna systems as well as the underlying radio architecture on large devices under test (DUTs). In one embodiment, the system consists of an X-Y gantry system capable of precisely moving a mounting structure to any location within a single plane, to which a robot arm is attached to manipulate the RF field probe. In other embodiments, the probe may be attached directly to the X-Y scanner. In some embodiments, the probe may be attached to a rotational positioner with one or two orthogonal axes capable of tilting and/or rotating the orientation of the probe relative to the reference coordinate frame of the system and/or as a function of X-Y position of the gantry. In such an arrangement, the available range of angles covered by the system would be defined by the arctangent of the range of motion of the gantry over the height of the probe above the AUT. In some embodiments, a linear positioner or other translational positioner capable of translation in at least one additional orthogonal orientation to the X-Y positioner may be used to vary the elevation. In some embodiments the positioner may be mounted on the rotating tilt arrangement mentioned previously. In other embodiments, the rotating tilt arrangement may be attached to the linear positioner or split into two separate axes on either side of the positioner. In one embodiment, the probe may be attached to a secondary carrier that rides on a curved arc that defines the radius of the probe system and produces both tilt and elevation changes by moving along the pre-defined curved path. In some embodiments, the arc may be attached to a rotational stage attached to the gantry carrier to create an orthogonal axis of rotation to that produced by the arc. In some embodiments, the arc may terminate at the rotational axis, while in others, it may support balanced operation along either side of the orthogonal rotating axis. The lower end of the arc may terminate at a height suitable for clearing the DUT, or may extend below an elevated DUT to allow capturing more than hemispherical coverage. In some embodiments, the moving carrier on the arc may be replaced with multiple probes for measuring different positions simultaneously. In some embodiments, the entire arc may rotate about an axis rather than the probe carrier moving on the arc. In some embodiments, the arc may be replaced by a straight armature or other structure capable of holding one or more probes oriented towards the center of a desired test volume. In some embodiments, the probe may tilt or move along the armature. In some embodiments, the armature may be multi-dimensional, allowing probes to be arranged to cover some portion of a surface around an AUT. It should be clear to one versed in the state of the art that the choice of coordinate orientations and the “UP” direction in all of these discussions is totally arbitrary. While certain orientations may be preferrable, embodiments of this invention could provide support from any direction about the DUT and scan above, below, to the side, or completely around the DUT. For the purposes of this discussion, the AUT will normally be assumed to be a planar array and the scan space will generally be “above” the DUT, but this is simply for convenience of illustration and should not be considered a limitation of the embodiments claimed herein.

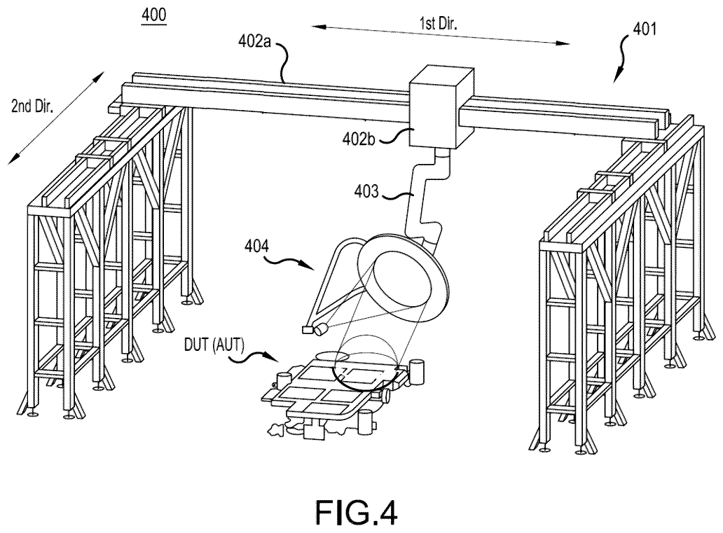

In some embodiments, the RF probe consists of a lightweight compact range reflector and feed assembly supporting one or multiple polarizations (e.g., FIG. 4 discussed below). In other embodiments, the probe may be a single or multiple individual antennas, a plane wave generator, an antenna with lens to create plane wave illumination, or other appropriate sensors or transmitters. In some embodiments, polarization may be controlled by rotating the feed to change polarization. In other embodiments, polarization may be controlled by rotating the entire reflector or probe assembly around the central axis of the projected quiet zone test volume.

In some embodiments, the reflector substrate is made of lightweight machinable foam. In other embodiments, the reflector is made from a thin carbon fiber or fiberglass shell. In still other embodiments, the reflector is made by molding various suitable plastics or other lightweight materials such as expansion foam. In other embodiments, the reflector is 3D printed. In each of the various dielectric embodiments, the reflector substrate (after suitable surface preparation) may be metalized by a number of techniques, including conductive paint, electroless plating, and vacuum metal deposition. Alternately, a thin metal shell could be created by processes such as electroforming and then attached to a lightweight (e.g., foam) structural substrate. In each embodiment, the structure for supporting the feed antenna may be integrated directly to the reflector and made of similar materials, or integrated separately of rigid materials for holding the feed at the proper location. In some embodiments, the feed support structure may include passive or active compensation mechanisms to correct for inherent sag between the feed and reflector caused by the varying direction of gravity as the system is moved about the AUT.

In some embodiments, the feed assembly will contain mechanisms for manipulating the position and orientation of the feed relative to the reflector. In some embodiments, the feed will be dual polarized while in other embodiments, the feed may have only a single polarization. The feed may be linearly polarized or circularly polarized in one or both orthogonal polarizations. In some embodiments, a feed roll axis may be provided to alter the polarization of the feed. In some embodiments, the feed may be broadband to cover the entire desired range of operation. In other embodiments, the feed and any associated components may be swappable using an alignment method to ensure that the replacement feed is on focus. In other embodiments, the entire CATR or probe assembly may be swapped on the positioning system to alter the frequency range or test volume size. In some embodiments, a rack for holding multiple CATR, probe, or feed assemblies may be integrated into the gantry system. In some embodiments, automated or semi-automated swapping of CATR, probe, or feed assemblies may be incorporated. In some embodiments, standard robotic tool change assemblies may be used to swap the feed, requiring only manual reconnection of cable assemblies. In other embodiments, blind-mate connectors may be used to avoid the need for manual cable connections.

In some embodiments, one or more of amplification, up/down conversion, and digital radio circuitry may be located proximal to the feed antenna, behind the reflector, or in the mobile structure of the gantry system. In some embodiments, test equipment including receivers, transmitters, network analyzers, or communication testers may be located behind the reflector or in the mobile structure of the gantry system. In other implementations, RF cables routed through the gantry system will carry signals back to a centralized location. In some embodiments, cable chains or other methods will be used to carry cables for RF signals, control signals, and power to the various components of the system. In some embodiments, the target RF/microwave signals are carried through the entire path, while in other embodiments up/down conversion is used at various points along the path to allow lower loss IF and LO signals to be carried along the longer distances of the system. In some embodiments, RF over fiber is used to replace the RF, IF, and/or LO signal cables with lightweight, low loss, and low-cost fiber optic cables that can easily handle the various bends associated with all of the axes of motion. In some cases, digital signals for control and/or data are carried over fiber optic cables.

In some embodiments, RF absorber (anechoic material) will be used to cover any exposed components of the positioning system and probe assembly that could cause unwanted signals to reflect back into the test volume. In some embodiments, the feed assembly will include an absorber “fence” to keep signals from the feed from reaching the test volume directly. In some embodiments, the support structure between the feed and reflector, as well as all cables and equipment will be covered with absorber to ensure that the feed signal to the reflector is not contaminated by reflections. In some embodiments, the robot arm or other armature mechanism, as well as the gantry components that may be exposed to spillover from the feed around the reflector or by direct or reflected paths from the reflector or probe assembly itself will also be covered with sufficient absorber to prevent significant multipath ripple within the test volume. In some embodiments, high power absorber may be used to ensure handling of high power densities produced by the focused plane wave signal. In some embodiments, forced air cooling may be used to remove excess heat. In other embodiments, pulse width modulated measurements may be used to limit the average power applied to the absorber.

In some embodiments, the system may use one or a combination of lasers for visual alignment of the test volume on the DUT. These lasers may have point, linear, crosshair, or other graticule arrangements for indicating the different degrees of freedom of the positioning system. The lasers may be mounted on each of the components of the X-Y gantry to highlight the locations of those components in the test volume. Alternately, or in addition, they may be mounted on the robot, armature, or probe/CATR assembly. For systems with a fixed targeted height to the quiet zone test volume, one or more fixed height laser assemblies may be mounted around the gantry or on the moving armature to indicate the height of the test volume. For fully flexible (e.g., robotic based) embodiments, the laser may be mounted on the moving arm or probe/CATR assembly. In some embodiments, the moving laser assembly may be mounted to coincide with the orientation of the probe or reflector and embedded in absorber to minimize its impact. In other embodiments, the laser may be mounted behind the probe or reflector with a known offset in orientation between the laser pointing direction and the centerline of the probe. During alignment, the probe is rotated away from the desired test volume and the laser is used to align the system. After alignment, the known offset is used to rotate the probe back to the now aligned coordinate system.

In some embodiments, one or more cameras may be used in place of or in addition to the lasers to perform DUT coordinate alignment. Digital reticules overlaid on the display may be used in place of or in addition to the lasers. Similar to the lasers, location of the cameras may be in locations that can be used while the system is in operation, or may be swung into position for the purposes of calibration and then hidden to avoid RF reflections and interference. In some embodiments, 3D cameras, sensors, photogrammetry, or other mechanisms may be used to generate a model of the DUT for alignment purposes and obstacle avoidance. In some embodiments, a CAD model of the DUT may be imported into controlling software to provide this map. Some embodiments may use any combination of the above.

A system for scanning radio frequency (RF) signals to and/or from a device under test (DUT) according to an embodiment of the inventive concepts will now be described with reference to FIG. 4.

Referring to FIG. 4, a system 400 for scanning radio frequency (RF) signals to and/or from a fixed device under test (DUT) within a volume of space around the DUT is shown. The DUT includes an antenna under test (AUT). The system 400 includes a gantry 401 having a carrier 402b robotically movable along a beam 402a in a first direction. As illustrated in the figure, the first direction may extend horizontally in parallel with a support surface of a chamber containing the system 400. Alternatively, the first direction may extend vertically in parallel with a wall of the chamber.

A robotic arm 403 is provided having a fixed end mounted to the carrier 402b and so as to extend from the beam 402a. The gantry 401 is configured to move the beam and thus the robotic arm 403 in a second direction orthogonal to the first direction. In some embodiments, the robotic arm 403 may have at least four degrees of freedom, providing flexibility in positioning the RF probe. In other embodiments, the robotic arm 403 may have at least six degrees of freedom, providing additional flexibility in positioning the RF probe.

An RF probe 404 is provided and mounted to a free end of the robotic arm 403. The RF probe 404 is configured to communicate with the AUT. The RF probe 404 may be a compact antenna test range (CATR) assembly. The CATR assembly is designed to generate a uniform plane wave that illuminates the AUT with a much lower total path loss and physical size than that is typically associated with direct far-field illumination.

A control system, not shown in the figure, is configured to coordinate movements of the gantry 401 and robotic arm 403 to move the RF probe 404 in a scanning pattern about the DUT. The scanning pattern allows the RF probe 404 to capture RF signals from various angles and positions around the DUT, providing a comprehensive evaluation of the AUT's performance.

As examples, the DUT may be a satellite, a terrestrial vehicle, an aircraft, a watercraft, or an aerospace vehicle. The volume of space traversed by the RF probe 404 is at least as large as the volume of space around the DUT. This allows the system 400 to accommodate DUTs of various sizes and shapes, making it versatile for testing a wide range of devices. As examples, the AUT may be a tracking antenna and/or a reflector, such as a parabolic dish, a reflectarray, a phased array and/or a reconfigurable intelligent surface (RIS).

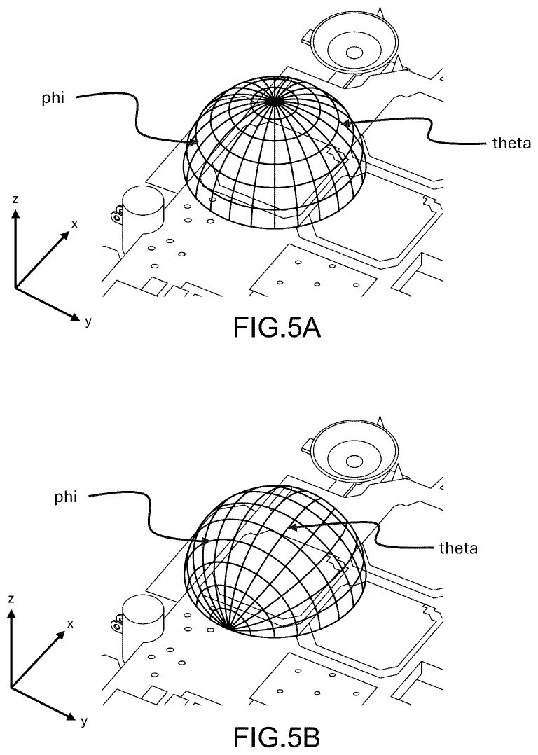

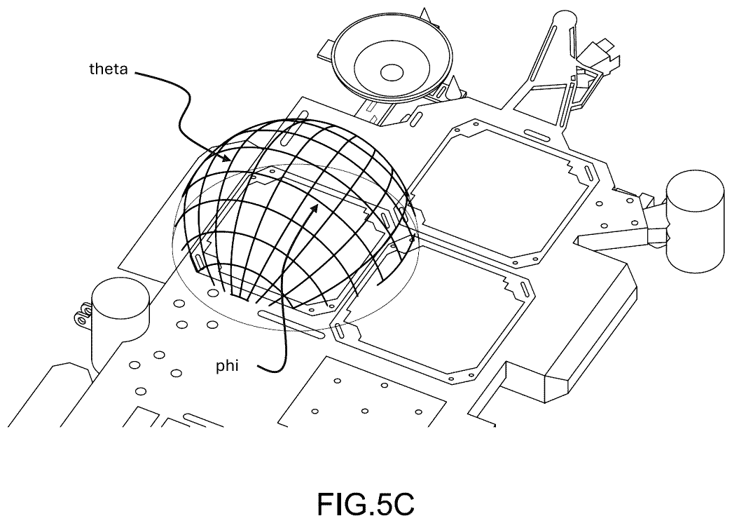

In order to perform the desired scans of an AUT, the probe must follow a given trajectory in space while maintaining the probe oriented towards the center of the test volume. In some embodiments, the required trajectory paths and positioner axis motions are pre-calculated on a controlling computer. In some embodiments, the motions are calculated on the fly in an embedded controller. In some embodiments, corrections for sag or other errors are applied based on each trajectory position or configuration in order to keep the probe on the desired trajectory path and orientation. In some embodiments, the trajectories are chosen to create paths on a spherical surface and measure data in spherical angular coordinates of theta and phi. In one such embodiment, the coordinate system is oriented in a polar configuration so that theta=0 along the orthogonal boresight direction of the AUT (i.e. the phi axis is along the boresight of the AUT) as shown in FIG. 5A discussed below. For a typical planar array, only the upper hemisphere would need to be measured, and due to clearance issues, coverage may not be possible beyond 60-75 degrees. For this coordinate system, conical cuts in phi (circular lines parallel to the x-y plane) can be taken for 360 degrees about the boresight phi axis for each step in theta from zero to the maximum allowed clearance. Alternately, partial great circle cuts in theta (arced lines extending vertically in the z-direction) can be made across the AUT between the negative and positive maximum extent of the theta angle. FIG. 5B, discussed below, illustrates an alternate embodiment of the spherical scan algorithm, where equatorial or azimuth/elevation coordinates are used about the boresight direction. In this case, the boresight of the AUT is in the equatorial plane, with the face of the AUT in a great circle cut plane (e.g. phi=+90 degrees) such that the poles of the spherical coordinate system are in the plane of the AUT. In this scenario, the hemisphere above the AUT would run from 0-180 degrees in theta, which corresponds to ±90 degrees in elevation from the boresight direction, and +90 degrees in phi or azimuth. It should be apparent to one skilled in the state of the art that the choice of (0,0) for the given coordinate system is somewhat arbitrary and any other desired combination can be used. Likewise, the orientation of the polar/phi axis can easily be chosen to be anywhere around the boresight axis in order to align the measurement coordinates with the desired usage coordinates of the DUT. Considering the case where clearance issues may prevent measuring the entire upper hemisphere, it should be noted that the range of the allowed angles for each cut varies around the hemisphere based on the total angle from the boresight axis, as illustrated in FIG. 5C discussed below.

Referring now to FIG. 5A, in one such system 400, the coordinate system is oriented in a polar configuration. In this configuration, theta equals zero along the orthogonal boresight direction of the antenna under test (AUT). This means that the phi axis is along the boresight of the AUT. This orientation allows for a comprehensive scanning of the AUT from various angles, providing a detailed evaluation of the AUT's performance. The polar configuration of the coordinate system enables the RF probe 404 to capture RF signals from various angles and positions around the DUT, providing a comprehensive evaluation of the AUT's performance.

It should also be noted that it is common to align the polarization direction of the probe to the coordinate direction of the test system, so for spherical scans, it is common to refer to the theta polarization and phi polarization as the polarization along those corresponding theta and phi directions of motion. This is typically accomplished by aligning the corresponding feed elements with the corresponding positioner axis so that they are always aligned correctly. However, given the flexibility of an overdetermined system like 400, which has an excess of degrees of freedom, the polarization directions are not constrained to remain along the desired coordinate system directions and therefore additional steps must be taken to choose paths that maintain the desired polarization orientation as well as the required pointing direction. This further constrains the allowed positions and paths in the robot workspace, although it does not eliminate all redundancies. Alternatively, for passive testing where phase information is available, various post processing techniques may be used to extract the desired polarization information from the measured data, given an associated reference of the actual polarization direction at each point during the test. It should also be noted that there are redundant polarization directions that simply differ by a sign in complex vector notation (180° in phase and physical space).

In some cases, the system 400 may be configured to adjust the orientation of the coordinate system based on the specific requirements of the testing process. For example, the system 400 may adjust the orientation of the coordinate system to accommodate DUTs of various sizes and shapes, making it versatile for testing a wide range of devices. In other cases, the system 400 may maintain a fixed orientation of the coordinate system throughout the testing process. This can simplify the testing process and reduce the complexity of the system 400.

It is also worth noting that the orientation of the coordinate system in a spherical polar configuration, as shown in FIG. 5A, is just one possible configuration. The system 400 may be configured to use other coordinate system orientations, such as Cartesian or cylindrical, depending on the specific requirements of the testing process. The choice of the coordinate system orientation can have a substantial impact on the accuracy and efficiency of the testing process, and is therefore an integral part of the system 400.

Turning to FIG. 5B, an alternate spherical scan algorithm is illustrated, where equatorial or azimuth/elevation coordinates are used about the boresight direction. In this case, the boresight of the AUT is in the equatorial plane, with the face of the AUT in a great circle cut plane (e.g., phi=+90 degrees) such that the poles of the spherical coordinate system are in the plane of the AUT. This configuration allows for a comprehensive scanning of the AUT from various angles, providing a detailed evaluation of the AUT's performance.

In this configuration, the system 400 may adjust the orientation of the coordinate system to accommodate DUTs of various sizes and shapes, making it versatile for testing a wide range of devices. The equatorial or azimuth/elevation configuration of the coordinate system enables the RF probe 404 to capture RF signals from various angles and positions around the DUT, providing a comprehensive evaluation of the AUT's performance.

It is again worth noting that the orientation of the coordinate system in an equatorial or azimuth/elevation configuration, as shown in FIG. 5B, is just one possible configuration. The system 400 may be configured to use other coordinate system orientations, depending on the specific requirements of the testing process. The choice of the coordinate system orientation can have a substantial impact on the accuracy and efficiency of the testing process, and is therefore an integral part of the system 400.

Turning to FIG. 5C, it is worth noting that the range of the allowed angles for each cut varies around the hemisphere based on the total angle from the boresight axis. This variation is due to the fact that the clearance issues may prevent measuring the full upper hemisphere. As a result, the range of the allowed angles for each cut is adjusted to accommodate these clearance issues, ensuring that the RF probe 404 can still capture RF signals from various angles and positions around the DUT.

In some cases, the system 400 may adjust the range of the allowed angles for each cut based on the specific requirements of the testing process. For example, the system 400 may increase or decrease the range of the allowed angles for each cut to accommodate DUTs of various sizes and shapes. This flexibility allows the system 400 to test a wide range of devices, making it versatile for various testing scenarios.

The range of the allowed angles for each cut, as shown in FIG. 5C, is just one possible configuration. The system 400 may be configured to use other ranges of allowed angles for each cut, depending on the specific requirements of the testing process. The choice of the range of the allowed angles for each cut can have a substantial impact on the accuracy and efficiency of the testing process, and is therefore an integral part of the system 400.

Given the collimated beam made possible by the CATR, it is not absolutely necessary to keep range length a constant. For other applications, it may be possible to correct for path loss and phase change as a function of distance from the AUT. Thus, in some embodiments, the choice may be made to scan while maintaining the probe system in a constant plane, and tilt the angle of the probe to remain on boresight to the AUT.

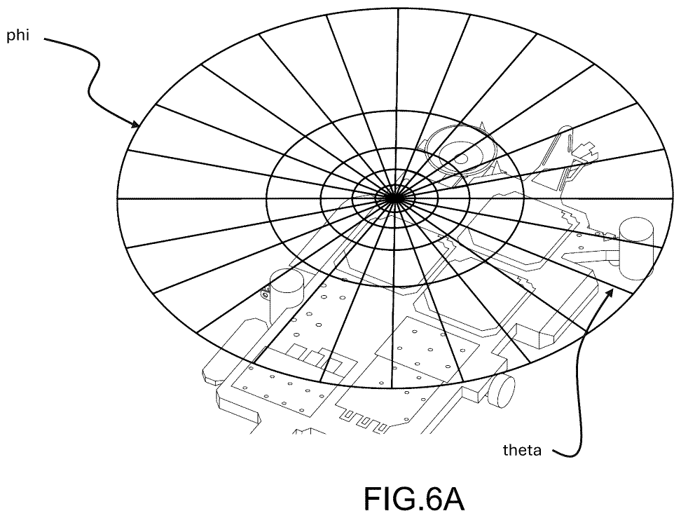

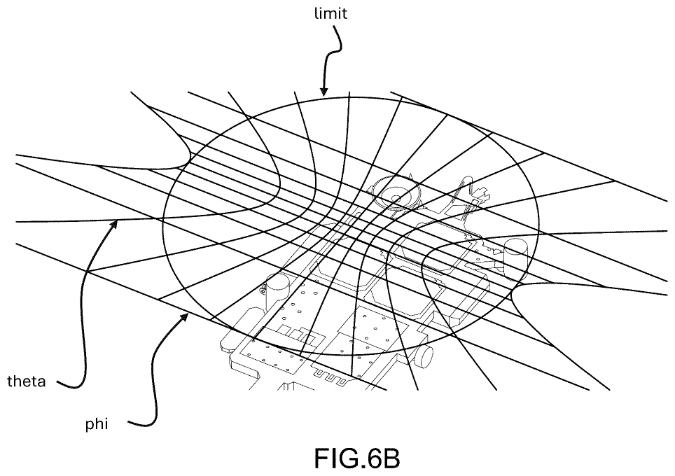

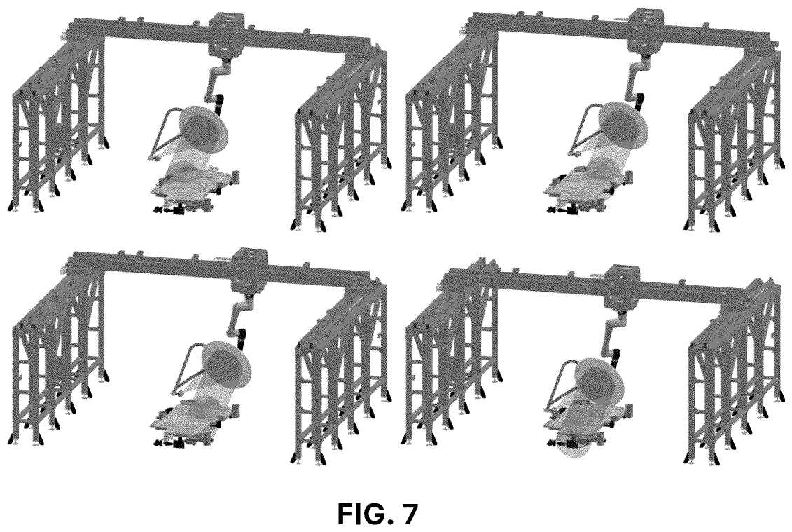

FIG. 6A illustrates the 15-degree grid from the polar spherical configuration in FIG. 5A projected on a plane for theta angles up to 75 degrees. It should be apparent that an infinite distance would be required to come close to theta=90 degrees. FIG. 6B illustrates the same 15-degree grid for the azimuth/elevation configuration in FIG. 5B projected on a plane for azimuth and elevation ranges up to +75 degrees in azimuth and elevation about the boresight. In this case, the issue as both angles approach 75 degrees becomes obvious, and the circle “limit” illustrates the same polar angle cutoff from the boresight direction at 75 degrees. It should be noted here that the planar scanning approach does require tighter tolerances on the angular pointing direction of the CATR probe, since small angular errors due to sag or other pointing errors can result in larger deviations in the position of the uniform illumination area from the reflector as the probe moves further away from the desired test region. This emphasizes the need for the calibration and validation of the positioning and the method for applying corrections as a function of the chosen trajectory.

It should be apparent that many other scanning surfaces and measurement grids may be used. For example, in some embodiments, cylindrical coordinates may be used, or Cartesian planar coordinates. In some embodiments, a conformal surface may be scanned around the DUT to maintain the minimum safe distance for the measurement. In some embodiments, an algorithm for uniformly spaced points (a constant density grid) may be used, either on a spherical surface, or any other desired surface. However, the spacing of the points on a spherical surface, for example, does not impose the requirement that the measurement be performed over the spherical surface.

Referring now to FIG. 7, in some cases, the volumetric positioning system may be used to alter the center coordinates of any of the aforementioned test volume configurations in order to scan different antenna under tests (AUTs) or other items at different locations on the device under test (DUT). This flexibility allows the system 400 to accommodate DUTs of various sizes and shapes, making it versatile for testing a wide range of devices. Alternately, multiple DUTs could be configured for test in the same total test volume and the system could automate scanning different DUTs sequentially.

As an aside, it is also critical that the system have adequate safety measures to protect both life and limb and the expensive devices to be tested, as well as the system components themselves. In some embodiments, the use of a collaborative robot (cobot) for the baseline device provides a torque based failsafe mechanism should anything ever come in contact with the robot and tool (e.g., CATR probe) and exert a resulting force beyond a given threshold. In other embodiments, the use of light curtains and door safety interlocks may be used to prevent motion when users are within the operating area. In addition to the collision protection features available on typical robots, some embodiments may use other sensors including sonar and lidar to provide real-time mapping and detection of objects around the perimeter of the reflector/probe assembly while avoiding affecting the RF testing being performed. Radar based solutions are likely to cause interference with the desired testing, but may be an option in some cases.

Alternately, or in addition, some embodiments may use stationary and/or carrier and/or probe mounted cameras to provide real-time optical tracking of the measurement system. Techniques including stereo vision, photogrammetry, etc. may be used to rapidly create a 3D model of the test environment and ensure that the measurement system is performing as expected and not entering pre-defined or automatically recognized keep-out areas where collisions may occur. In some systems, laser interferometry and/or one or more a laser trackers may be used both for real time feedback of the exact position of the probe system, and for compensation for sag and other errors. Alternately, the laser tracker may just be used at installation for calibration of the system.

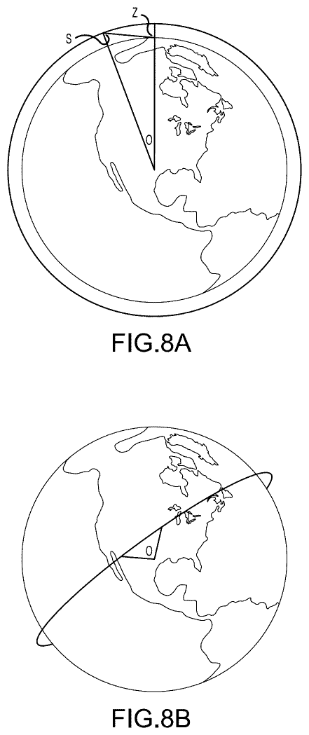

Another test application supported by the volumetric scanning system of the inventive concepts is to allow trajectory tracking, where a phased array or mechanical tracking antenna is evaluated for its ability to maintain a communication link to a moving endpoint (e.g., a satellite or moving vehicle). In this scenario, the desired path is unlikely to be represented by a simple motion in theta or phi of any single spherical axis, and will rarely reach zenith directly over the antenna element. In even the simplest “static” case, the positioning system needs to be able to follow a complicated angular path across the upper hemisphere. In some embodiments of the inventive concepts, the system is equipped with a second RF probe, and is configured to coordinate movements of the two RF probes to emulate respective first and second terrestrial base stations in communication with the satellite while in orbit or two satellites in communication with a fixed or mobile ground station. Likewise, the antenna(s) under test could be equipped on other vehicles such as aircraft or automobiles. This aspect of the inventive concepts is described next in connection with FIGS. 8A through 12.

Referring to FIGS. 8A and 8B, the relationship between the angle from zenith for both the satellite and ground station and the corresponding orbital angle is illustrated. In these figures, the range of azimuth angles over which communication is maintained is projected on the surface of the Earth.

FIG. 8A illustrates the relationship between the angle from zenith for both the satellite and ground station and the corresponding orbital angle, and FIG. 8B shows the range of azimuth angles over which communication must be maintained projected on the surface of the Earth. The corresponding orbital angle is shown in relation to the angle from zenith for both the satellite and ground station. The azimuth angle corresponds to the direction of the satellite from the ground station in the horizontal plane. The orbital angle corresponds to the position of the satellite in its orbit, and the angle from zenith corresponds to the angle between the line of sight from the ground station to the satellite and the vertical direction. The relationship between these two angles determines the trajectory that the RF probe follows during the scanning process.

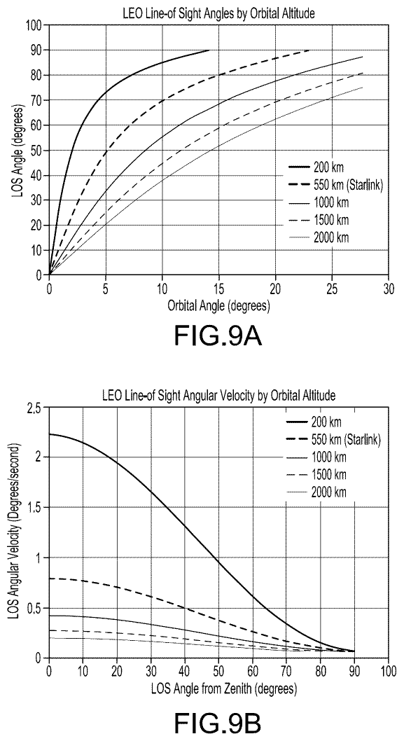

FIGS. 9A and 9B plot the range of zenith angles for a satellite passing directly overhead (FIG. 9A) and the corresponding angular velocities seen by the ground station as the satellite passes (FIG. 9B). Any given trajectory would have to emulate the azimuth and zenith angles associated with the desired orbit to ground station relationship, as well as the associated angular velocities. Note that this only illustrates the effect of a static ground station and orbital motion. A mobile endpoint on an aircraft or automobile could see a much greater angular velocity to the apparent angle of arrival/departure when, for example, the vehicle is banking or turning. In such scenarios where gantry and probe motion are insufficient to simulate the required rate of motion, an additional positioner may be required to provide rotation of the DUT in at least one axis of motion.

In FIG. 9A, the range of zenith angles for a satellite passing directly overhead is plotted. The zenith angle corresponds to the angle between the line of sight from the ground station to the satellite and the vertical direction. The range of zenith angles determines the range of positions that the RF probe 404 can occupy during the scanning process. This range of positions allows the RF probe 404 to capture RF signals from various angles and positions around the DUT, providing a comprehensive evaluation of the AUT's performance.

In FIG. 9B, the corresponding angular velocities seen by the ground station as the satellite passes are plotted. The angular velocity corresponds to the rate of change of the angle between the line of sight from the ground station to the satellite and the vertical direction. The range of angular velocities determines the speed at which the RF probe 404 moves during the scanning process. This speed affects the rate at which the DUT/AUT must be able to adapt its pattern to track the simulated satellite or remote terminal.

In addition to the physical angle(s) of arrival and departure simulated by the tracking system 400, it may also be desirable to emulate the Doppler, delay, and propagation losses caused by the real distance and rate of motion of the remote endpoint relative to the device under test, as opposed to the relatively slow motion and distances created by the tracking system. In some embodiments, therefore, RF channel emulation may be used to inject desired impairments into the RF signal path, including Doppler, delay, atmospheric and propagation path losses, multi-path, etc.

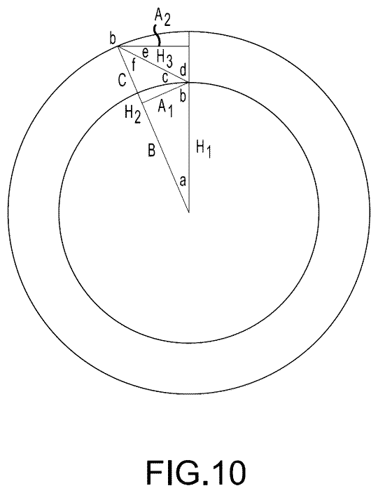

FIG. 10 shows a collection of variables that are used to solve the simple zenith trajectory case of FIGS. 9A and 9B. That is, the figure shows the variables that are used to calculate the trajectory of the RF probe during the scanning process. Other trajectories become considerably more complex, but can be solved relatively easily using vector algebra.

Therefore, in one embodiment, the positioning system and control software would use orbital mechanics to calculate a desired trajectory and replay that real-time as the communication link is evaluated. In some embodiments, channel emulation or other communication test methods may be used to simulate expected time/position dependent channel impairments such as the change in path loss and Doppler as a function of the real satellite distance and velocity, as well as expected atmospheric losses, dispersion, multipath, etc. In another embodiment, the positioning system may be configured to follow real-time trajectory information that is fed from another emulator or simulation source. In yet another embodiment, the motion of the second endpoint (e.g., a plane or RV) could be added to the scenario with additional alterations to the trajectory to simulate banking or turning a corner. It should also be obvious to one skilled in the art that other trajectory scenarios are possible, including vehicle to terrestrial network scenarios and vehicle to vehicle scenarios, in terrestrial, airborne, or space configurations or any combination thereof.

Likewise, the trajectory calculations could be done to exercise the behavior of either endpoint. In one embodiment, these positions and velocities would be replayed on the surface of a sphere about the AUT, while in an alternate scenario, they could be generated along a planar surface or other desired geometry similar to that for the spherical measurement grids.

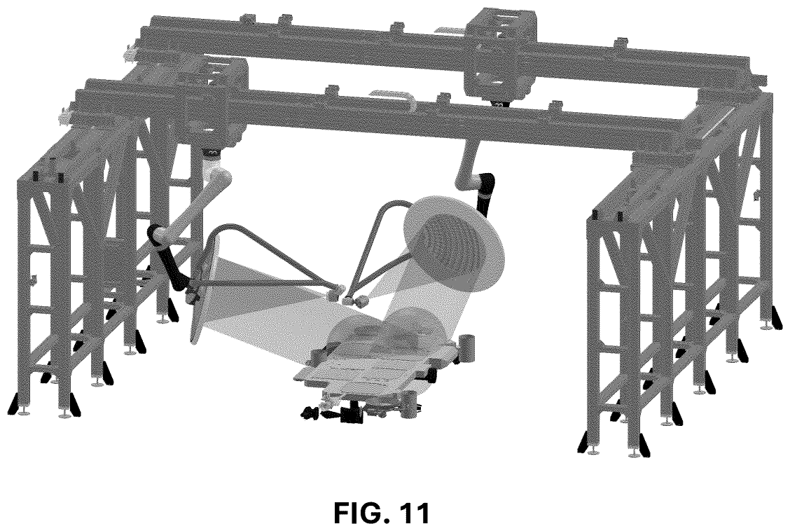

Expanding on the concept of trajectory tracking, another important test case is to evaluate handover scenarios, where, for example, one satellite may be moving out of range (setting) while another is coming into range (rising). The same scenario also exists on the satellite as it transitions from one ground station to another and must maintain the backhaul link for all active end users as it transitions. FIG. 11, discussed next, illustrates one embodiment of a system for testing such a scenario, where a second gantry beam and carrier with a second robot arm and CATR probe are used to generate a second plane-wave beam to the desired test volume. For the test method embodiment shown, each probe is illuminating a different AUT on the DUT in order to test handover between simultaneous beams in different directions from different phased arrays on the DUT.

Referring to FIG. 11, system 400a according to an embodiment of the inventive concepts is shown. The system 400a includes a second gantry beam 405a and carrier 405b with a second robot arm 406 and CATR probe 407 are used to generate a second plane-wave beam to the desired test volume is illustrated. In this configuration, each probe may be illuminating a different AUT on the DUT. This setup allows for the testing of handover between simultaneous beams in different directions from different phased arrays on the DUT.

In this system 400a, the second gantry beam 405a and carrier 405b are configured to move in a similar manner as the first gantry beam and carrier, providing a second degree of freedom for the movement of the second robot arm 406. The second robot arm 406 is mounted to the second carrier 405b and extends from the second gantry beam 405a. The second robot arm 406 may have at least four degrees of freedom or at least six degrees of freedom, providing flexibility in positioning the second RF probe 407.

The second RF probe 407 is mounted to a free end of the second robot arm 406 and is configured to communicate with a different AUT on the DUT. The second RF probe 407 may be a CATR assembly, similar to the first RF probe. The CATR assembly is designed to generate a uniform plane wave that illuminates the AUT with a much lower total path loss and physical size than that is typically associated with direct far-field illumination.

A control system, not shown in the figure, is configured to coordinate movements of the second gantry beam 405a, second carrier 405b, and second robot arm 406 to move the second RF probe 407 in a scanning pattern about the DUT. The scanning pattern allows the second RF probe 407 to capture RF signals from various angles and positions around the DUT, providing a comprehensive evaluation of the performance of the different AUTs on the DUT.

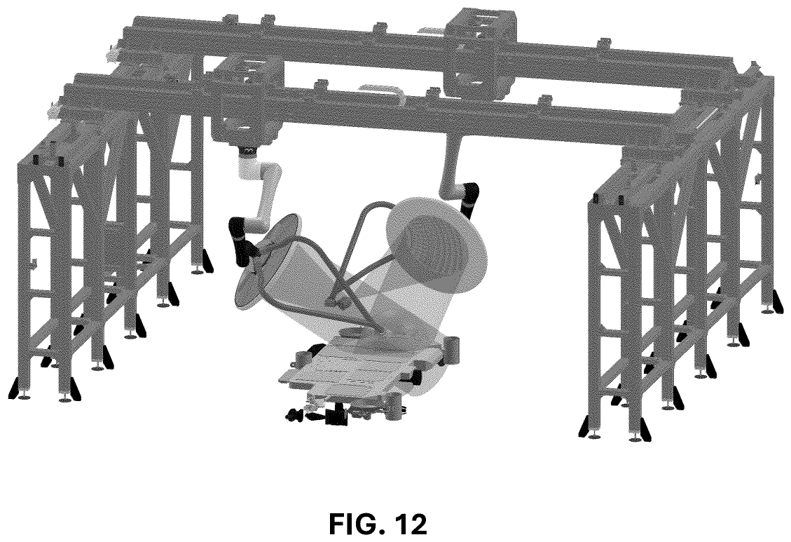

The same system 400a could be used in other methodology to test other scenarios such as MIMO/massive MIMO, multiple simultaneous beams from the same AUT, or signal-to-interference (SIR) testing on a single AUT as shown in FIG. 12. Other scenarios include testing of beam-forming RF repeaters, reconfigurable intelligent surfaces, or other “bent-pipe” scenarios where the transmit and receive angles of arrival and departure can vary. Likewise, with appropriate radar signal emulation, these scenarios could be used to simulate radar targets at various distances and relative angles. This flexibility allows the system 400a to accommodate a wide range of testing scenarios, making it versatile for various testing applications.

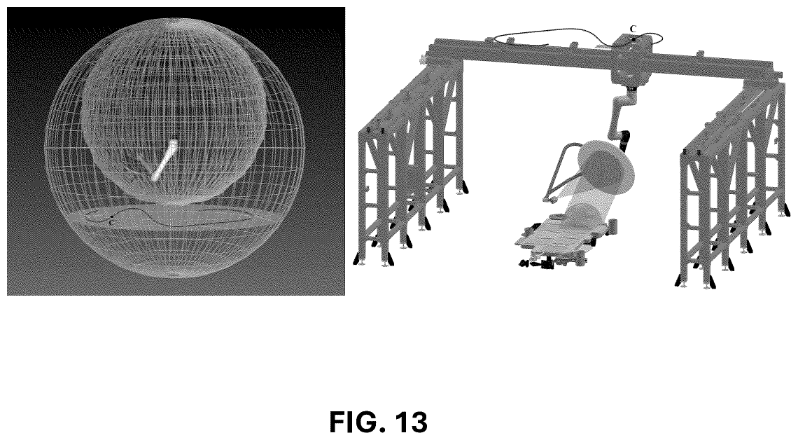

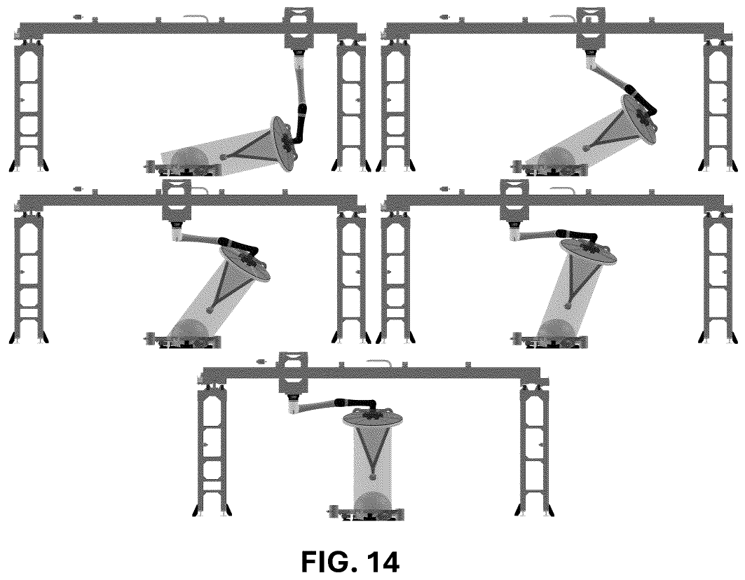

While a robotic arm generally has more degrees of freedom than should be required to emulate two spherical axes of motion, physical size constraints and potential collision points, as well as the physical location of the robot base relative to the AUT, greatly reduce the available workspace as discussed previously However, as illustrated in FIG. 13, given a collision free path of the center point C in the green plane such that all desired angles of incidence can be reached sequentially (e.g. from theta=0-75 degrees) without encountering an obstruction, then an embodiment of the system and associated algorithm need only move the base of the robot opposite the path of motion of C in the robot tool workspace in order to maintain C at the desired center of the test volume as the probe is moved through the desired range of angles. The net effect in the DUT coordinate system is that the point C remains fixed while the base of the robot moves along the reverse of the path in the robot workspace.

With eight degrees of freedom in the six-axis robot plus two-axis gantry system, there are still likely to be multiple viable paths, although not all will be optimal in terms of the total amount of motion, rate of motion of each axis, etc. Paths that minimize the overhung load, maximize the available angular velocity in the spherical coordinate system, and minimize vibrations or other perturbations are preferable to paths that switch directions or have sharp changes in motion of various axes. One way to constrain the system is to prioritize certain axes of motion over others. Another solution would be to lock certain axes in a specific configuration in order to reduce the total degrees of freedom.

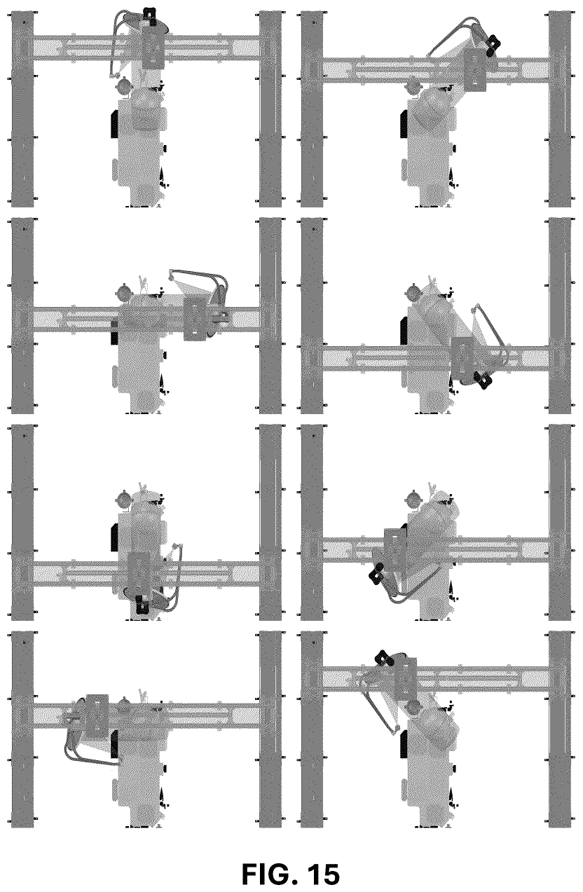

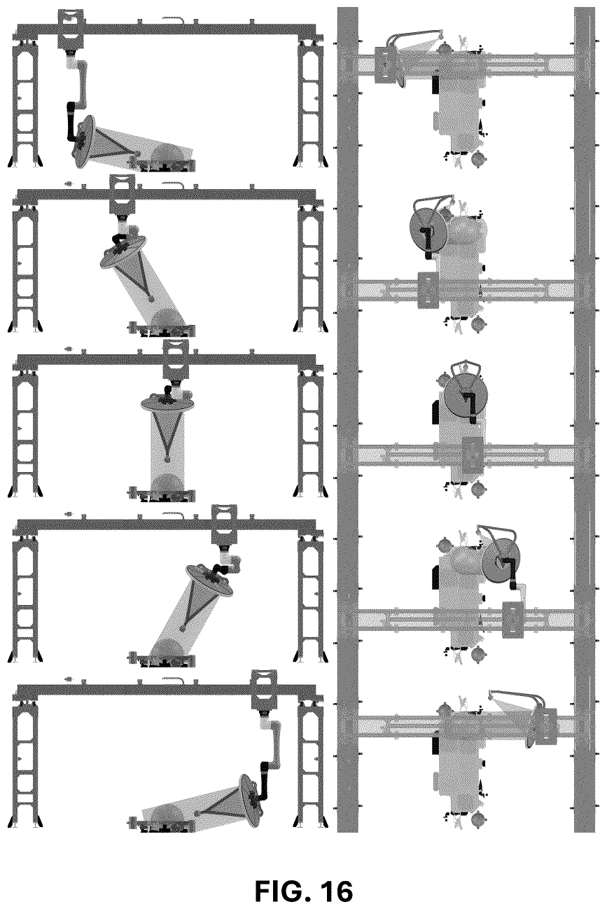

For example, in one embodiment as represented in FIG. 14, the elbow can be locked with the arm nearly straight (avoiding a positioning singularity in the elbow joint at the straight position) and the adjacent wrist joint of the robot can be kept in an almost right-angle orientation that gives the maximum angular extension of the reflector/probe when the arm is near vertical, with the joint constrained to remain parallel to the desired theta cut plane. In this scenario, the entire range of motion from theta equal zero to the maximum is accomplished through the second “tilt” axis of the shoulder joint and the gantry moving radially along a line perpendicular to the tilt axis to a position approximately proportional to the cosine of the theta angle (and the corresponding tilt angle). Due to height vs. range length vs. robot arm length constraints, the wrist joint must still make minor adjustments along the arc as well. For a constant angular velocity, the linear velocity of the gantry must vary according to the cosine of the theta angle as well. In this embodiment, referring to FIG. 15, the phi-axis rotation is accomplished by moving the X-Y gantry in a circle at the current radius associated with the theta angle and rotating the top vertical shoulder joint of the robot in the opposite direction to compensate for the circular motion of the gantry carrier and robot base. Thus, by simply adding a few constraints, the motion calculation reduces from eight independent axes to three or four tightly coupled motions for movement in theta and phi. It should be noted that with a slightly larger gantry, or through the use of the elbow for the remaining motion, the full theta cut from −Theta Max to +Theta Max could be reached in one cut if desired. However, that may require reversal of motion on the gantry for a portion of the motion, which is somewhat undesirable.

An alternate embodiment of the scan algorithm using similar methods would remove the constraint that the gantry carrier and robot arm move parallel to the plane of the theta rotation of the reflector but instead, constrain the carrier on the gantry to remain (roughly) in the plane perpendicular to the movement plane and coincident with the wrist of the robot. In this scenario, the arm would again remain extended for all positions, but rather than the carrier moving in a radial line, it would follow a circular arc as the reflector moved up and across the test volume as shown in FIG. 16. Phi rotation would still be accomplished in the same manner as in the previous embodiment.

It should be apparent to one skilled in the art that these are just two possible embodiments of a motion algorithm possible by following a simple set of rules.

One challenge for any mechanical positioning system used for RF measurements is that the amount of time required to accelerate and decelerate between measurement points becomes excessive as the angular resolution of the measurement is increased. The smaller step size means that the positioner does not have time to accelerate to a high speed before it has to decelerate and stop. Thus, a standard industry practice is to generate trigger signals to synchronize on-the-fly measurements to be recorded at a specific step size. This is relatively straightforward to accomplish with a single-axis positioner having a digital encoder by using a simple count-to-N counter to count the encoder pulses as the positioner moves and automatically generate a trigger pulse when the counter rolls over. The value of N specifies the periodicity of the trigger in position units and will accurately cause measurements to occur at the desired position, regardless of whether or not the positioner is accelerating, decelerating, or moving at a constant speed. Likewise, a stepper motor controller could count steps and generate the desired trigger pulse when it signals to take the next step corresponding to the desired trigger count.

However, once motion goes beyond a single axis, the previous approaches no longer work, because the desired trigger position is no longer a property of a single axis of motion. Querying each axis and determining the current position in order to generate a required trigger pulse or command to perform a measurement is also not a valid approach, since the associated communication latency would always cause the trigger to be delayed well beyond the desired trigger point. In some cases, it may be possible to compensate with a skew correction, but the skew will vary as a function of velocity and will be in the opposite direction when positions are measured in reverse order.

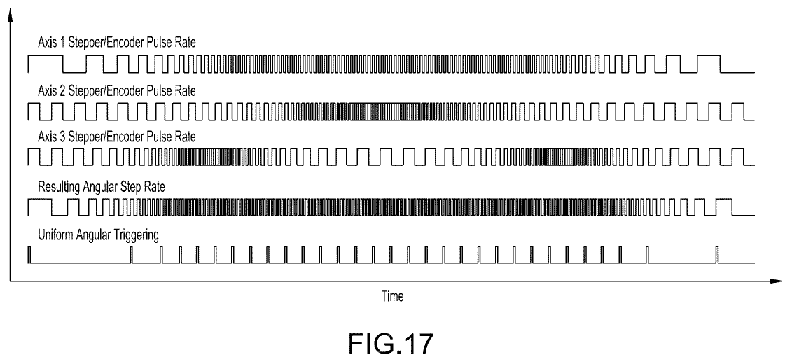

In order to avoid this problem, one possible embodiment of the positioning algorithm as described earlier, which would need to either pre-calculate or calculate on-the-fly, the positions (steps and/or encoder counts) of each of the eight axes of motion as a function of time, would calculate the corresponding trigger times in parallel based on the desired triggering angles/positions. Then, through a similar mechanism that streams the position information to each of the motor drives, the trigger pulses would be generated at the appropriate time based on the parallel streams. FIG. 17, discussed below, illustrates the use of multiple axes with varied rates of motion to produce a single motion of the probe tool about a virtual axis and triggering generated proportional to the resulting angular motion rate. This approach can of course be scaled to anything from two synchronized axes of motion to much more complicated positioning systems.

Referring to FIG. 17, an approach is illustrated where multiple axes with varied rates of motion are used to produce a single motion of the probe tool about a virtual axis. In this configuration, triggering is generated proportional to the resulting angular motion rate. This approach allows the system to accurately capture RF signals from various angles and positions around the DUT, providing a comprehensive evaluation of the AUT's performance.

In this scenario, the varied rates of motion of the multiple axes allow the probe tool to follow a complex trajectory around the DUT. This trajectory is determined by a virtual axis, which is a conceptual axis that guides the motion of the probe tool. The virtual axis is not a physical component of the system 400, but rather a mathematical construct that is used to calculate the trajectory of the probe tool.

The triggering of the RF probe is generated proportional to the resulting angular motion rate. This means that the rate at which the RF probe 404 captures RF signals is adjusted based on the speed at which the probe tool moves along the trajectory. This allows the system 400 to maintain a constant angular velocity during the scanning process, ensuring accurate and efficient testing of the AUT.

An alternative embodiment to position-based trigger acquisition is to perform free running (sample-based) or time-based trigger acquisition where the trigger pulse associated with each measurement, generated by the measurement device or an external timer, is also fed to the positioning system in order to log the current position of all drive axes simultaneously. The actual angular position of the probe can then be determined real-time or in post processing in order to align the measured data with the associated position. While this may produce non-uniform angular spacing of the data, for the trajectory-based scenarios, where angular velocity will vary intentionally, this approach makes much more sense, capturing data continuously as a function of time rather than angle.

As mentioned previously, the AUT may for example include a reflector, a reflectarray or a RIS. This is particularly the case where a two-arm solution such as that of FIGS. 11 and 12. For example, transmitting and receiving from different directions may be carried out to evaluate how the RIS redirects the incoming wave. This may be referred to as a bistatic arrangement used to evaluate reflectivity and scattering of an object.

Importantly, although the term AUT (antenna under test) has been used herein to categorize the reflectarray and RIS, it will be understood that this is for descriptive purposes only and that the reflectarray and RIS may not necessarily be considered an “antenna” in the traditional sense. The term reflectarray refers to a specific concept for creating the equivalent of a parabolic reflector using a flat panel array of elements. RIS then takes the reflectarray concept and adds the ability to tune the elements to steer the generated beam. In any event, the term AUT is to be interpreted generically to encompass traditional antenna systems (e.g. a feed horn plus reflector for a parabolic dish antenna or patch antenna elements+phase/gain circuitry for a phased array) and to encompass reflectarrays, RIS and similar devices, as well as combinations thereof.

In addition, as mentioned in the examples given in the preceding paragraph, the antenna system may include multiple parts, each of which may be independently tested. The term AUT encompasses each of the individual components as well as the combination of components making up the system. For example, a bistatic reflector test generally refers to transmitting from one probe in one direction and receiving from another probe in another direction to test how the DUT echoes that signal. The AUT, or reflector under test, could be anything from a simple reflector or passive reflectarray (possibly even mechanically adjusted), to various forms of active arrays that may simply amplify the reflected signal, or in full RIS, control the direction of the reflected signal. Eventually, this becomes difficult to distinguish from a full repeater that receives a signal on one antenna, amplifies and conditions it, and retransmits from the same or another antenna.

In short, the term AUT is to be broadly construed to encompass any one or more transmitting and/or receiving components and sub-components of the DUT, including mechanical and electrical steering mechanisms.

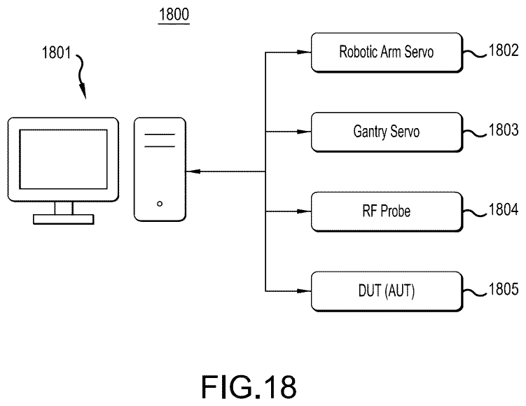

Referring now to FIG. 18, a generic control system 1800 is illustrated. The control system 1800 includes a computer system 1801 that communicates with a gantry servo 1802, a robot servo 1803, RF probe control circuits 1804, and DUT control circuits 1805. The computer system 1801 serves as the central processing unit of the control system 1800, coordinating the movements of the gantry 401 and the robotic arm 403, and controlling the operation of the RF probe 404 and DUT. Note that in this context, the term “servo” is used to refer to any controlled positioning system type, including servomotors, stepper motors, etc., and may included low level feedback (encoder or step position of each axis) and high level feedback (e.g. laser tracking or optical feedback of the position of the end effector/probe). The feedback may be direct to the servo positioning controller or through higher level control from the computer system 1801 or other components.

In the case of the system of FIG. 4, the gantry servo 1802 controls the movement of the beam 402a in the second direction and the carrier 402b in the first direction. The gantry servo 1802 receives commands from the computer system 1801 and translates these commands into mechanical movements of the carrier 402b along the beam 402a. This allows the gantry 401 to position the fixed end of robotic arm 403 anywhere in a two-dimensional plane above the DUT.

The robot servo 1803 controls the movement of the robotic arm 403. The robot servo 1803 receives commands from the computer system 1801 and translates these commands into mechanical movements of the robotic arm 403. This allows the robotic arm 403 to position the RF probe 404 at various angles and positions around the DUT.

The RF probe control circuits 1804 control the operation of the RF probe 404. This category would include any additional RF test equipment (network analyzer, spectrum analyzer, communication tester, or other RF endpoint, channel emulation, amplification, up/down conversion, etc.) used to facilitate the RF measurements through the probe antenna(s). The RF probe control circuits 1804 receive commands from the computer system 1801 and translate these commands into operational parameters of the RF probe 404. This allows the RF probe 404 to communicate with the AUT and capture RF signals from various angles and positions around the DUT.

The DUT control circuits 1805 control the operation of the DUT. The DUT control circuits 1805 receive commands from the computer system 1801 and translate these commands into operational parameters of the DUT. This allows the DUT to operate in a manner that facilitates the testing process.

Although not illustrated in FIG. 18, for proper synchronization, in addition to the command and control information from computer system 1801, timing and control signals are commonly required between various components 1802-1805 of the system. For example, the robotic arm servo control and gantry servo control must be synchronized in time to allow for synchronous motion of the robot and gantry in order to maintain the probe at the desired location. This may be through external synchronization signals or by using a combined servo control system that is internally synchronized to control both the gantry and robot positioning. Likewise, the trigger signals mentioned previously may be required between the servo control subsystem(s) 1802 and 1803 and the RF probe subsystem 1804 and/or DUT control subsystem 1805 in order to control the state of the DUT (e.g. the chosen antenna pattern or active element at each point in time and position) and the measurement of said state by the RF probe subsystem.

It is worth noting that the configuration of the control system 1800, as shown in FIG. 18, represents just one possible configuration. The system 400 may be configured to use other control systems, depending on the specific requirements of the testing process. As one skilled in the art will appreciate, the choice of the control system can have a substantial impact on the accuracy and efficiency of the testing process.

What is claimed is:

1. A system for scanning radio frequency (RF) signals to and/or from a fixed device under test (DUT) within a volume of space around the DUT, the DUT including an antenna under test (AUT), the system comprising:
a gantry having a carrier robotically movable along a beam in a first direction;
a robotic arm having a fixed end mounted to the carrier and extending from the beam, the gantry configured to move the robotic arm along the beam in a second direction orthogonal to the first direction;
an RF probe mounted to a free end of the robotic arm and configured to communicate with the AUT; and
a control system configured to coordinate movements of the gantry and robotic arm to move the RF probe in a scanning pattern about the DUT.

2. The system of claim 1, wherein the first and second directions extend horizontally in parallel with a support surface of a chamber containing the system, and the robotic arm extends upwardly or downwardly from the beam.

3. The system of claim 1, wherein the first direction extends horizontally and the second direction extends vertically, and the robotic arm extends horizontally from the beam.

4. The system of claim 1, wherein the robotic arm has at least four degrees of freedom.

5. The system of claim 1, wherein the robotic arm has at least six degrees of freedom.

6. The system of claim 1, wherein the RF probe is a reflector and feed assembly.

7. The system of claim 1, wherein the DUT is a satellite, a terrestrial vehicle, an aircraft, a watercraft or an aerospace vehicle, and a volume of space traversed by the RF probe is at least as large as the volume of space around the DUT.

8. The system of claim 1, wherein the AUT is at least one of a tracking antenna or a reflector.

9. The system of claim 8, wherein the AUT is at least one of a horn, array, or reflector-based antenna, or a static or active reflector such as. reflectarray a reconfigurable intelligent surface (RIS).

10. A method for scanning radio frequency (RF) signals to and/or from a fixed device under test (DUT) within a volume of space around the DUT, the DUT including an antenna under test (AUT), the method comprising:
providing a gantry having a carrier robotically movable along a beam in a first direction;
providing a robotic arm having a fixed end mounted to the carrier and extending from the beam, the gantry configured to move the robotic arm along the beam in a second direction orthogonal to the first direction;
providing an RF probe mounted to a free end of the robotic arm and configured to communicate with the AUT; and
coordinating movements of the gantry and robotic arm to move the RF probe in a scanning pattern about the DUT.

11. The method of claim 10, wherein the first and second directions extend horizontally in parallel with a support surface of a chamber containing the system, and the robotic arm extends downwardly from the beam.

12. The method of claim 10, wherein the first direction extends horizontally and the second direction extends vertically, and the robotic arm extends horizontally from the beam.

13. The method of claim 10, wherein the robotic arm has at least four degrees of freedom.

14. The method of claim 10, wherein the robotic arm has at least six degrees of freedom.

15. The method of claim 10, wherein the RF probe is a compact antenna test range (CATR) assembly.

16. The method of claim 10, wherein the DUT is a satellite, a terrestrial vehicle, an aircraft, a watercraft or an aerospace vehicle, and a volume of space traversed by the RF probe is at least as large as the volume of space around the DUT.

17. The system of claim 10, wherein the AUT is at least one of a tracking antenna or a reflector.

18. A system for scanning radio frequency (RF) signals to and/or from a fixed device under test (DUT) within a volume of space around the DUT, the DUT including at least one antenna under test (AUTs), the system comprising:
a gantry having a first carrier robotically movable along a first beam in a first direction, and a second carrier robotically movable along a second beam in the first direction, each of the first and second beams movable along a second direction orthogonal to the first direction;
a first robotic arm having a fixed end mounted to the first carrier and extending from the first beam, the gantry configured to move the first robotic arm with the first beam in the second direction;
a second robotic arm having a fixed end mounted to the second carrier and extending from the second beam, the gantry configured to move the second robotic arm with the second beam in the second direction;
a first RF probe mounted to a free end of the first robotic arm and configured to communicate with an AUT among the at least one AUT;
a second RF probe mounted to a free end of the second robotic arm and configured to communicate with an AUT among the at least one AUT; and
a control system configured to coordinate movements of the gantry and first and second robotic arms to move the first and second RF probes in a scanning pattern about the DUT.

19. The system of claim 15, wherein the DUT is a satellite, and the control system is configured to coordinate movements of the first and second RF probes to emulate respective first and second terrestrial base stations in communication with the satellite while in orbit.

20. The system of claim 18, wherein the DUT is a satellite, a terrestrial vehicle, an aircraft, a watercraft, or an aerospace vehicle, and each of the at least one AUT is a tracking antenna or a reflector.
